(19) United States
(12) Patent Application Publication
(10) Pub. No.: US 2003/0009726 A1
(43) Pub. Date: Jan. 9, 2003

(54) Method and apparatus for the formation of laminated circuit having passive componets therein

(75) Inventors: Han-Chieh Chang, Taipei (TW); Chang-Ming Chen, Hsinchu (TW); Hsuan Peng, Taipei (TW); Min-Wen Wang, Hsinchu (TW)

Correspondence Address: BROWDY AND NEIMARK, P.L.L.C., 624 NINTH STREET, NW, SUITE 300, WASHINGTON, DC, 20001-5303, US

(73) Assignee: INDUSTRIAL TECHNOLOGY RESEARCH INSTITUTE, HSINCHU (TW)

(21) Appl. No.: 09/972,953

(22) Filed: Oct. 10, 2001

(30) Foreign Application Priority Data
Jul. 4, 2001 (TW) 90116311

(51) Int. Cl. G06F 17/50; H05K 3/30; H01R 3/00; B23P 19/00; B05C 5/00

(52) U.S. Cl. 716/1; 29/832; 29/729; 118/300

(57) ABSTRACT

A method of forming a laminated circuit is described as follows: designing the laminated circuit in computer, recording the circuit layout of the laminated circuit into a data file subject to a predetermined format, inputting the data file into the main control unit of a laminated circuit forming apparatus for conversion into sequential control signals to drive insulative material sprayer, conductive material sprayer, and impedance material sprayer to eject respective fluid insulative materials onto a platform at different times and locations subject to the sequential control signals, forming the desired laminated circuit having an insulative body, electric circuits and passive components in it.

### FIELD OF THE INVENTION

The present invention relates to electronic circuits and, more specifically, to a method and apparatus for the formation of laminated circuit having passive components therein.

### BACKGROUND OF THE INVENTION

Regular electric circuit boards (having electronic elements) for use in electronic products are commonly made by: designing the circuit layout in computer, converting the circuit layout into a Gerber file (a file format commonly used in the fabrication of circuit boards), making a negative film subject to the Gerber file, developing the circuit layout on a copper foil bonded glass fiber plate, processing the copper foil bonded glass fiber plate into the finished circuit board through etching, pressing, drilling, film-bonding, electroplating, electronic element plugging, and soldering procedures. This fabrication method is complicated, resulting in high manufacturing cost.

### SUMMARY OF THE INVENTION

The present invention has been accomplished to provide a laminated circuit fabrication method and apparatus, which simplifies the fabrication of laminated circuit, and reduces the manufacturing cost of laminated circuit.

The method of the present invention comprises the steps of (a) using a software in a computer to design a laminated circuit comprised of electrically insulative substrates, electric circuits, and passive components; (b) recording the circuit layout of the laminated circuit into a data file subject to a predetermined format; (c) inputting said data file into a laminated circuit forming apparatus comprised of a main control unit, a platform, an insulative material sprayer, a conductive material sprayer, an impedance material sprayer, and a driving unit; and (d) operating the main control unit of the laminated circuit forming apparatus to convert the inputted data file into sequential control signals to drive the driving unit, causing the driving unit to move the platform and the insulative material sprayer, the conductive material, and the impedance material sprayer relative to one another, and to drive the insulative material sprayer, the conductive material, and the impedance material sprayer to eject respective fluid insulative material, fluid conductive material and fluid impedance material onto the platform at different times and locations subject to the sequential control signals, forming the desired laminated circuit having an insulative body and electric circuits and passive components embedded in the insulative body.

The apparatus for the formation of laminated circuit having passive components therein comprises a platform, an insulative material sprayer, a conductive material sprayer, an impedance material sprayer, a driving unit adapted to move the platform, the insulative material sprayer, the conductive material sprayer, and the impedance material sprayer relative to one another, and a main control unit adapted to covert a data file of a predetermined format recording the circuit layout of a laminated circuit into sequential control signals to control the operation of the driving unit, causing the driving unit to move the platform, the insulative material sprayer, the conductive material sprayer, and the impedance material sprayer relative to one another, and to control the insulative material sprayer, the conductive material sprayer, and the impedance material sprayer to eject fluid insulative material, fluid conductive material, and fluid impedance material onto the platform at times and locations subject to the sequential control signals to form the desired laminated circuit.

### BRIEF DESCRIPTION OF THE DRAWINGS

FIG. 1 is an elevational view of a laminated circuit made according to the present invention.

FIG. 2 is a sectional view taken along line 2-2 of FIG. 1.

FIG. 3 is a sectional view taken along line 3-3 of FIG. 2.

FIG. 4 is an enlarged view of the left upper corner of the array converted from the laminated circuit shown in FIG. 3.

FIG. 5 is a system block diagram of a laminated circuit forming apparatus according to the present invention.

FIG. 6 is a longitudinal view in section of an alternate form of laminated circuit made according to the present invention.

FIG. 7 is a longitudinal view in section of an alternate form of laminated circuit made according to the present invention.

### DETAILED DESCRIPTION OF THE PREFERRED EMBODIMENT

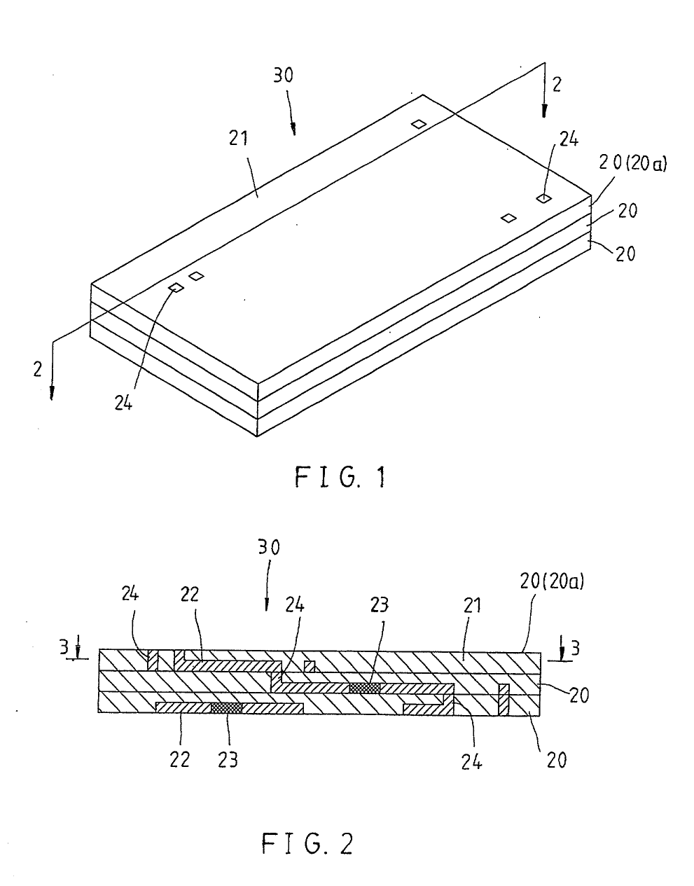

The method of the present invention is outlined hereinafter. At first, use software in a computer to design the desired circuit. FIGS. 1 and 2 are the elevational and cross-sectional views of the finished product of the designed circuit. As illustrated, the laminated circuit 30 is comprised of multiple circuit layers 20 laminated upon one another. The structure of each circuit layer 20 is similar to a conventional circuit board, comprising an electrically insulative substrate 21, electric circuits 22 arranged in the substrate 21, and passive components 23 (including resistors, inductors, or capacitors) bridged to the electric circuits 22. Unlike conventional circuit boards, the electric circuits and the electronic elements are embedded in the bottom side inside the substrate 21. The electric circuits 22 of each circuit layer 20 have protruded top connecting portions 24 formed at predetermined points and extended to the top surface of the respective circuit layer 20. The protruded top connecting portions 24 of the circuit layer 20 below are respectively connected to the electric circuits 22 of the circuit layer 20 above (the protruded top connecting portions 24 of the topmost circuit layer 20a are input/output terminals for the connection of other active and/or passive components, or an external circuit). By means of this design, the electric circuits of all circuit layers 20 are connected subject to the design, forming a laminated circuit.

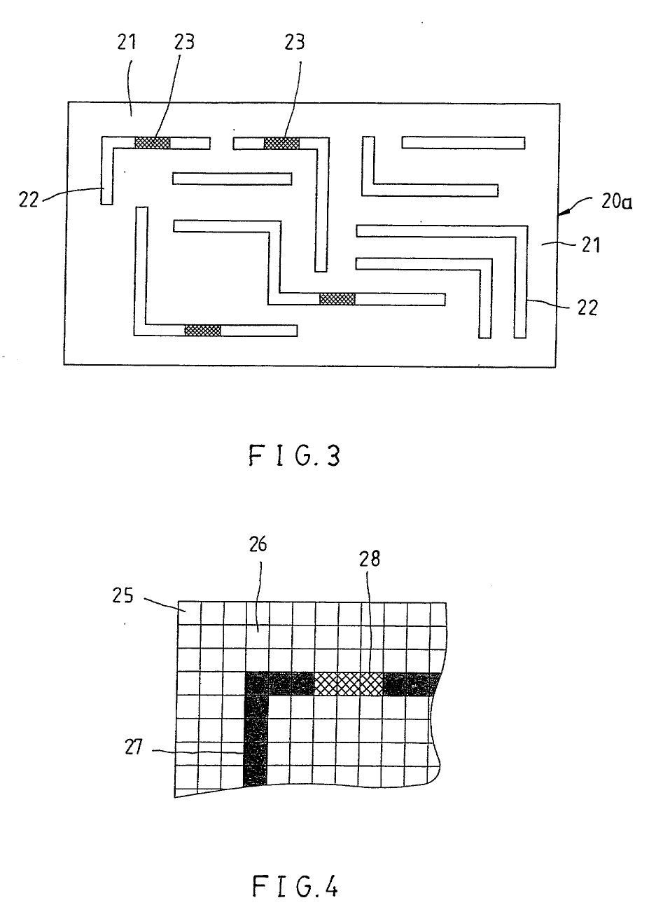

After the design of the desired laminated circuit, record the circuit layout of the designed laminated circuit in a data file of a particular format (for example, Gerber file). Converting the circuit layout into digital data is achieved by means of, for example, the following method. Assume the circuit layout of the topmost circuit layer 20a of the laminated circuit 30 is as shown in FIG. 3 (which is a cross-sectional view taken along line 3-3 of FIG. 2), thus the planar circuit layout is regarded as an array of multiple small squares. In this case, the circuit layer 20a is as shown in FIG. 4 (the drawing shows only its left upper corner), i.e., corresponding to the substrate 21, electric circuit 22, or passive components 23 of the circuit layer 20a, every small square 25 should be insulative substance 26, metal conductor 27, or impedance substance having a particular impedance 28. Subject to this rule, the layout of every circuit layer 20 of the laminated circuit 30 is converted into a data array of X lines by Y rows (the number of lines and rows is determined subject to the density of the circuit). The data array records the characteristics, such as insulator or conductor, connected or disconnected to the upper circuit layer, of every X-Y coordinate of the respective circuit layer 20, and the related parameter (impedance value, inductance value, or capacitance value). All the data arrays of the circuit layers 20 are arranged together, forming a data file representing the laminated circuit 30. Please bear in mind that the above statement is a concept description, not an actual equation deduction.

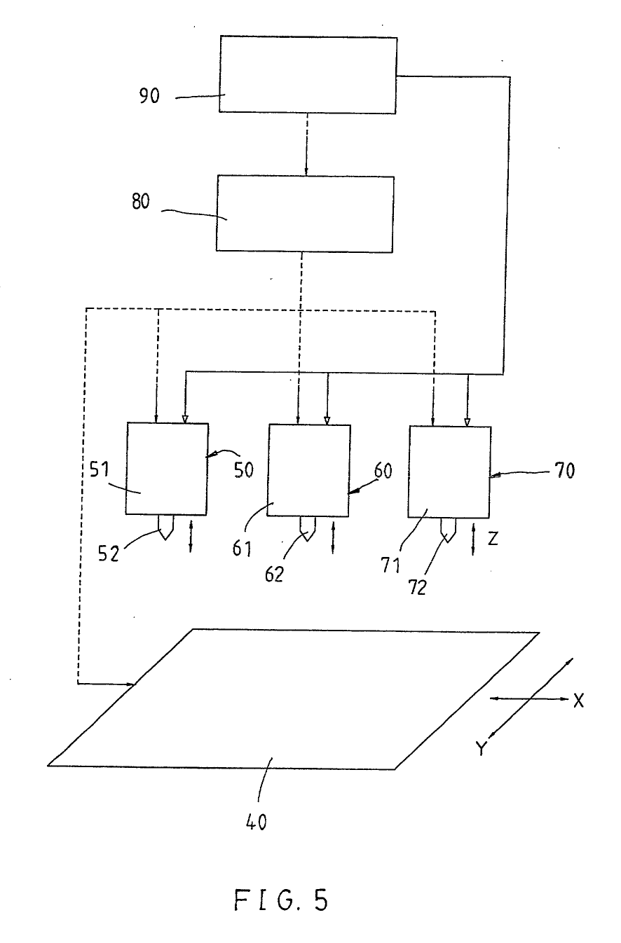

Thereafter, input the data file thus obtained into a circuit forming apparatus. The apparatus, as shown in FIG. 5, comprises a platform 40, which is a XY platform controlled to move leftwards/rightwards and forwards/backwards horizontally, an electrically insulative material sprayer 50, an electrically conductive material sprayer 60, an impedance material spray 70, a driving unit 80, and a main control unit 90. The sprayers 50, 60 and 70 have a respective storage tank 51, 61 or 71. According to the present preferred embodiment, the storage tank 51 of the electrically insulative material sprayer 50 holds fluid engineering plastics; the storage tank 61 of the electrically conductive material sprayer 60 holds fluid tin silver alloy; the storage tank 71 of the impedance material spray 70 holds fluid graphite. Storage tanks 51, 61 and 71 are respectively heated to keep the respective fluid storage material in the fluid status. The sprayers 50, 60 and 70 each further comprise a jet nozzle 52, 62 or 72 extended from the respective storage tank 51, 61 or 71 and suspending above the platform 40. The jet nozzle 52, 62 or 72 is a high-precision device (like the printing head of an ink printer) that can be controlled to accurately transiently eject a small amount of fluid onto a spot area. The driving unit 80 is controlled to move the jet nozzles 52, 62 and 72 and the platform 40 relative to one another in a three-dimensional relationship. According to the present preferred embodiment, the driving unit 80 is controlled to move the jet nozzles 52, 62 and 72 in Z-axis direction, and to move the platform in X-axis and Y-axis directions. The main control unit 90 receives the aforesaid data file, converts the data file into sequential control signals (this will be described further), and then outputs the sequential control signals to the driving unit 80 and the sprayers 50, 60 and 70, causing the driving unit 80 to move the platform 40 and the eject nozzles 52, 62 and 72 to the set positions in proper order and the eject nozzles 52, 63 and 72 to eject the respective storage fluid material onto the platform 40 at respective determined positions.

The main control unit 90 is programmably controlled to drive the platform 40 and the sprayers 50, 60 and 70 subject to the circuit layout recorded in the data file, causing insulative material, conductive material, and impedance material to be ejected onto predetermined locations on the platform 40 to form the desired laminated circuit 30. During shape forming, the designed circuit layers 20 are formed on the platform 40 one over another. During the formation of one circuit layer 20, the respective electric circuits 22 and passive components 23 are formed on the platform 40, and then the substrate 21 is formed in the other area. In detail, when the main control unit 90 reads in the message that one particular X-Y coordinate should be conductor, it immediately controls the driving unit 80 to move the platform 30 to the position right below the jet nozzle 62 of the electrically conductive material sprayer 60, and then drives the jet nozzle 62 to eject a spot of fluid tin silver alloy downwards onto the platform 40 (the spot of fluid tin silver alloy is quickly condensed after been driven out of the jet nozzle 62). If the coordinate is the point to be connected to the circuits of an upper circuit layer, the spraying time of the jet nozzle 62 will be relatively longer, enabling a protruded connecting portion to be formed on the conductor of ejected tin silver alloy. In the same manner, if a coordinate should be electrically insulative material, the platform 40 is moved to the position right below the jet nozzle 52 of the electrically insulative material sprayer 50, and then the jet nozzle 52 is driven to eject a spot of engineering plastics onto the platform 40. Different passive components 23 (resistors, inductors, capacitors) are formed in different ways. The jet nozzle 72 of the impedance material spray 70 is controlled to eject fluid graphite onto the platform 40 at predetermined locations, forming the desired resistors. By means of controlling the concentration of fluid graphite, resistors of different impedance are obtained. The formation of inductors and capacitors can be made by means of the combining electrically conductive material, electrically insulative material or impedance material. After formation of the electric circuits 22 and passive components 23 of one circuit layer 20, fluid engineering plastics is ejected onto every coordinate at the circuit layer 20 (except the protruded connecting portions 24), forming the desired substrate 21, which is disposed in flush with the topmost edge of the protruded portions 24. After formation of one circuit layer 20, the jet nozzles 52, 62 and 72 are lifted to a distance equal to the thickness of one circuit layer, and then a new circuit layer is formed on the top side of the duly formed circuit layer 20. This procedure is repeated again and again until the complete of the desired laminated circuit 30.

Multiple storage tanks may be used for each sprayer to store different concentrations of fluid material, and selectively controlled by the main control unit to output the respective storage fluid material to the respective jet nozzle. For example, the impedance material sprayer can be made having multiple storage tanks storing different concentrations of fluid graphite, so that different concentrations of fluid graphite can be selectively driven out of the jet nozzle of the impedance material sprayer to form resistors of different impedance, or different concentrations of fluid graphite can be combined with fluid conductive material or fluid insulative material to form inductors of different inductance value or capacitors of different capacitance value. Further, different fluid materials may be used with the aforesaid sprayers instead of engineering plastics, tin silver alloy, and graphite. For example, ceramic material may be used for the insulative material; copper may be used for the conductive material.

The aforesaid laminated circuit 30 is comprised of multiple circuit layers 20 laminated upon one another. The present invention can also be employed to produce a three-dimensional circuit structure, or a single layer electronic circuit.

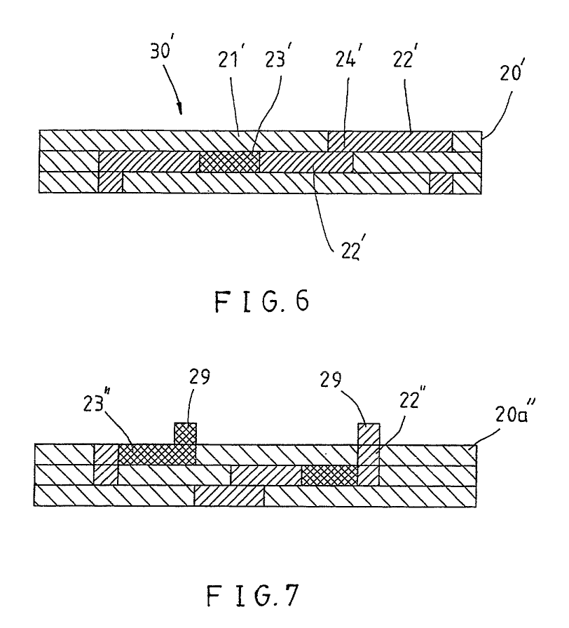

FIG. 6 shows another structure of laminated circuit according to the present invention. The laminated circuit 30′ is comprised of multiple circuit layers 20′ laminated upon one another. Unlike the structure of the laminated circuit 30 shown in FIG. 2, the circuits 22′ and passive components 23′ of each circuit layer 20′ of the laminated circuit 30′ are disposed in flush with the top and bottom surfaces of the respective circuit layer 20′ (i.e., the protruded connecting portions 24 shown in FIG. 2 are eliminated in this alternate form), and the circuits 22′ of each two adjacent circuit layers 20′ are electrically connected at predetermined coordinates (indicated by reference sign 24′). This design provides a three-dimensional circuit layout. The circuit forming apparatus for this alternate circuit design needs not to form the protruded connecting portions on the circuits 22′, and is controlled to eject fluid insulative material onto the platform at the area beyond the coordinates of the circuits 22′ and the passive components 23′.

FIG. 7 shows still another structure of laminated circuit according to the present invention. According to this design, protruded connecting portions 29 are formed on the circuits 22″ and passive components 23″ of the top circuit layer 20a″ and protruded over the top surface of the top circuit layer 20a″ to work as input/output terminals for communication with external circuit, or for the connection of active components such as ICs and transistors.

A prototype of method and apparatus for the formation of laminated circuit having passive components therein has been constructed with the features of FIGS. 1˜7. Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A method for the formation of laminated circuit having passive components therein, comprising the steps of:
a) using a software in a computer to design a laminated circuit comprised of electrically insulative substrates, electric circuits, and passive components;
b) recording the circuit layout of said laminated circuit into a data file subject to a predetermined format;
c) inputting said data file into a laminated circuit forming apparatus comprised of a main control unit, a platform, an insulative material sprayer, a conductive material sprayer, an impedance material sprayer, and a driving unit;
d) operating the main control unit of said laminated circuit forming apparatus to convert the inputted data file into sequential control signals to drive said driving unit, causing said driving unit to move said platform, said insulative material sprayer, said conductive material sprayer, and said impedance material sprayer relative to one another, and to drive said insulative material sprayer, said conductive material sprayer, and said impedance material sprayer to eject respective fluid insulative material, fluid conductive material and fluid impedance material onto said platform at different times and locations subject to said sequential control signals, forming the desired laminated circuit having an insulative body and electric circuits and passive components embedded in the insulative body.

2. The method as defined in claim 1, wherein said laminated circuit is comprised of at least two laminated flat circuit layers, said flat circuit layers each comprising an electrically insulative substrate having a bottom side and a top side, and the components circuits and passive components embedded in the bottom side of the electrically insulative substrate, the electric circuits of one flat circuit layer in a lower side of said laminated circuit having protruded connecting portions extended to the top side of the respective electrically insulative substrate and connected to the circuits of the flat circuit layer above; said laminated circuit forming apparatus is controlled to form the flat circuit layers of said laminated circuit from a bottom side toward a top side layer by layer in the sequence of forming the circuits and passive components for one flat circuit layer and then forming the electrically insulative substrate for the respective flat circuit layer.

3. The method as defined in claim 1, wherein said laminated circuit is comprised of at least two laminated flat circuit layers, said flat circuit layers each comprising an electrically insulative substrate having a bottom side and a top side, and the electric circuits and passive components embedded in the electrically insulative substrate in flush with the top and bottom sides of the electrically insulative substrate, the electric circuits of one flat circuit layer being connected to the electric circuits of another flat circuit layer at predetermined coordinates; said laminated circuit forming apparatus is controlled to form the flat circuit layers of said laminated circuit from a bottom side toward a top side layer by layer.

4. The method as defined in claim 1, wherein said laminated circuit has said circuits or said passive components protruded over a top surface thereof.

5. The method as defined in claim 1, wherein said insulative material sprayer is controlled to eject fluid engineering plastics to form the electrically insulative substrate for each flat circuit layer of said laminated circuit.

6. The method as defined in claim 1, wherein said conductive material sprayer is controlled to eject fluid tin silver alloy to form said electric circuits in said laminated circuit.

7. The method as defined in claim 1, wherein said impedance material sprayer is controlled to eject fluid graphite to form said passive components in said laminated circuit.

8. The method as defined in claim 1, wherein said impedance material sprayer is controlled to eject different concentrations of fluid impedance material to form resistors of different impedance value in said laminated circuit.

9. The method as defined in claim 1, wherein said impedance material sprayer, said insulative material sprayer, and said conductive material sprayer are controlled to eject different concentrations of fluid impedance material, fluid insulative material, and fluid conductive material to form inductors of different impedance value in said laminated circuit.

10. The method as defined in claim 1, wherein said impedance material sprayer, said insulative material sprayer, and said conductive material sprayer are controlled to eject different concentrations of fluid impedance material, fluid insulative material, and fluid conductive material to form capacitors of different capacitance value in said laminated circuit.

11. An apparatus for the formation of laminated circuit having passive components therein, said apparatus comprising:
a platform;
an insulative material sprayer, said insulative material sprayer comprising a jet nozzle suspended above said platform and adapted to eject fluid insulative material downwardly onto said platform;
a conductive material sprayer, said conductive material sprayer comprising a jet nozzle suspended above said platform and adapted to eject fluid conductive material downwardly onto said platform;
an impedance material sprayer, said impedance material sprayer comprising a jet nozzle suspended above said platform and adapted to eject fluid impedance material downwardly onto said platform;
a driving unit adapted to move said platform, said insulative material sprayer, conductive material sprayer, and impedance material sprayer relative to one another; and
a main control unit adapted to covert a data file of a predetermined format recording the circuit layout of a laminated circuit into sequential control signals to control the operation of said driving unit, causing said driving unit to move said platform, said insulative material sprayer, said conductive material sprayer, and said impedance material sprayer relative to one another, and to control said insulative material sprayer, said conductive material sprayer, and said impedance material sprayer to eject the respective fluid insulative material, fluid conductive material, and fluid impedance material onto said platform at times and locations subject to said sequential control signals to form the desired laminated circuit.

12. The apparatus as defined in claim 11, wherein the jet nozzle of said insulative material sprayer is adapted to eject fluid engineering plastics onto said platform.

13. The apparatus as defined in claim 11, wherein the jet nozzle of said conductive material sprayer is adapted to eject fluid tin silver alloy onto said platform.

14. The apparatus as defined in claim 11, wherein the jet nozzle of said impedance material sprayer is adapted to eject fluid graphite onto said platform.

15. The apparatus as defined in claim 11, wherein the jet nozzle of said impedance material sprayer is controllable to eject different concentrations of fluid impedance material.

16. The apparatus as defined in claim 11, wherein said insulative material sprayer, said conductive material sprayer, and said impedance material sprayer each have a plurality of storage tanks connected to the respective jet nozzle to provide different concentrations of fluid material.
